(19) United States
(12) Patent Application Publication
(10) Pub. No.: US 2013/0228740 A1
(43) Pub. Date: Sep. 5, 2013

(54) LIGHT-EMITTING DIODE DEVICE

(71) Applicants: Yen-Chang HSIEH, Hsinchu City (TW); Ya-Hsuan SHIH, Changhua County (TW)

(72) Inventors: Yen-Chang HSIEH, Hsinchu City (TW); Ya-Hsuan SHIH, Changhua County (TW)

(73) Assignee: PHOSTEK, INC., Taipei City (TW)

(21) Appl. No.: 13/455,991

(22) Filed: Apr. 25, 2012

(30) Foreign Application Priority Data
Mar. 2, 2012 (TW) 101107119

(51) Int. Cl. H01L 27/15; H01L 33/06

(52) U.S. Cl. 257/13; 257/E27.121; 257/E33.008

(57) ABSTRACT

A light-emitting diode (LED) device includes at least one LED unit. Each LED unit includes at least one LED. Each LED includes an n-side nitride semiconductor layer, a p-side nitride semiconductor layer, and an active layer that is located between the n-side nitride semiconductor layer and the p-side nitride semiconductor layer. The active layer is includes one or more well layers. At least one of the well layers has a multilayered structure.

### BACKGROUND OF THE INVENTION

1. Field of the Invention

The present invention generally relates to a light-emitting diode (LED) device, and more particularly to a group III-Nitride LED device.

2. Description of Related Art

A conventional light-emitting diode (LED) may have a homojunction structure or a heterojunction structure. A homojunction LED primarily includes an n-doped layer and a p-doped layer, which include the same material and thus have the same energy gap. A p-n junction is formed between the n-doped layer and the p-doped layer.

A heterojunction LED primarily includes a bottom cladding layer, an active layer, and a top cladding layer. The bottom/top cladding layer and the active layer have different materials and thus have different energy gaps. As a result, carriers may be confined in the active layer to form a well region.

The heterojunction LED is the more commonly used LED. The heterojunction LED's active layer typically includes a single quantum well (SQW) or a multi quantum well (MQW) with an energy gap smaller than the energy gap of the cladding layer. The energy gap difference increases re-combination rate of electrons and holes, luminescence efficiency, and light emitting output. The MQW has a greater light emitting output than the SQW, but, however, has a greater thickness that raises serial resistivity and its forward voltage.

As the quantum well structure in the LED is restricted in use, a photoluminescence (PL) lifetime and a carrier overflow cannot be effectively shortened, and a radioactive recombination rate therefore cannot be effectively enhanced.

Accordingly, a need has arisen for a novel quantum well structure that enhances the luminescence efficiency and the light emitting output.

### SUMMARY OF THE INVENTION

In certain embodiments, at least one light-emitting diode (LED) unit includes at least one LED. The LED includes an n-side nitride semiconductor layer, a p-side nitride semiconductor layer, and an active layer located between the n-side nitride semiconductor layer and the p-side nitride semiconductor layer. The active layer includes one or more well layers. At least one of the well layers has a multilayered structure.

### BRIEF DESCRIPTION OF THE DRAWINGS

FIG. 1A shows a cross section of an embodiment of a light-emitting diode (LED) device.

FIG. 1B shows a cross section of an embodiment of a conventional LED device.

FIG. 1C shows a cross section of an embodiment of an LED device.

FIG. 2A shows an exemplary energy band diagram of the conventional LED in FIG. 1B.

FIG. 2B shows an exemplary energy band diagram of the LED in FIG. 1C.

FIG. 3 shows an exemplary internal quantum efficiency (IQE) comparison between the LED of FIG. 1B and the LED of FIG. 1C.

FIG. 4 shows a cross section of another embodiment of an LED device.

FIG. 5 shows a perspective diagram illustrating an embodiment of an LED device.

### DETAILED DESCRIPTION OF THE INVENTION

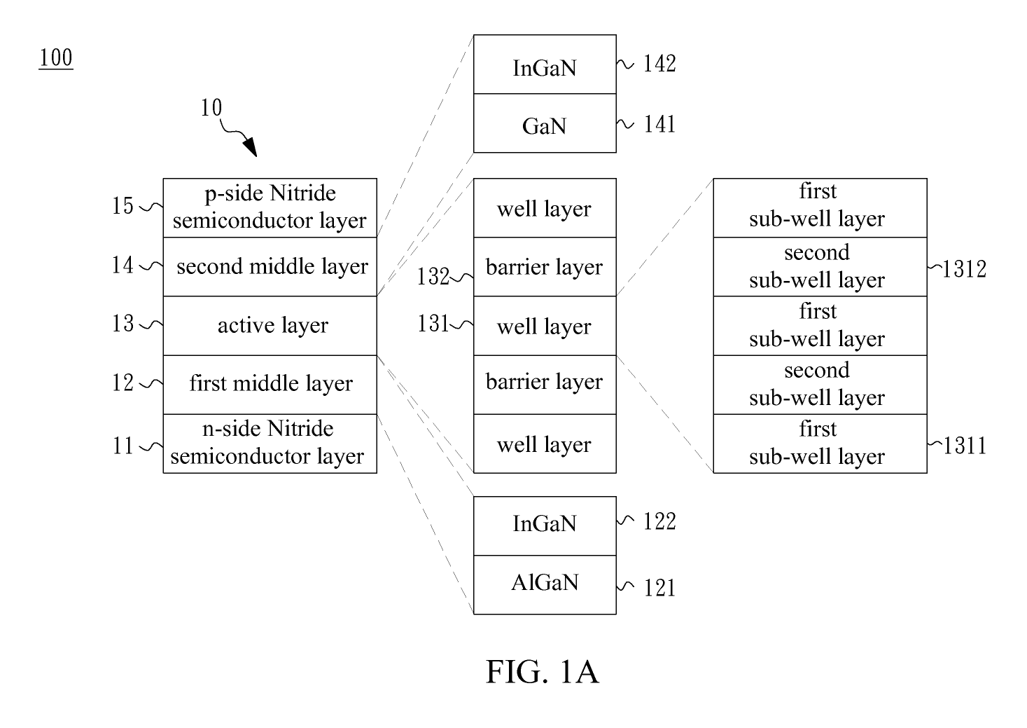

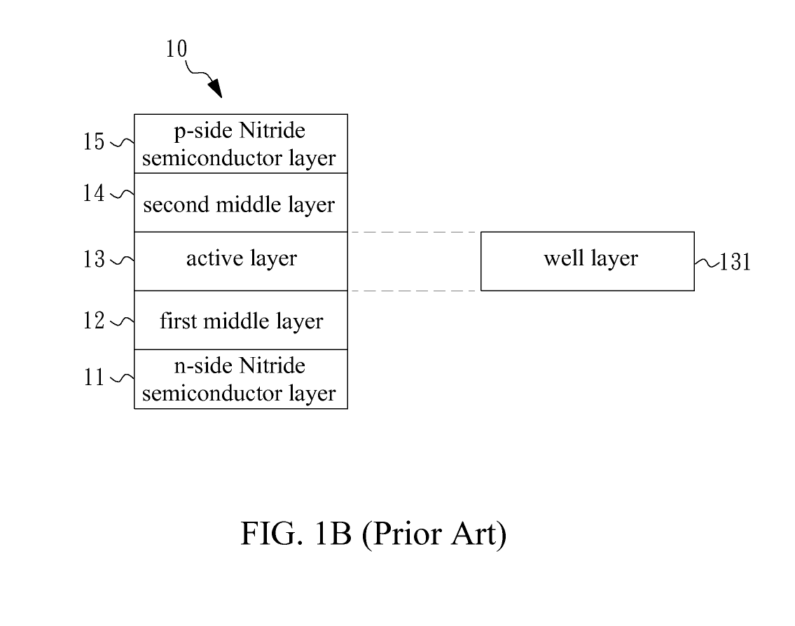

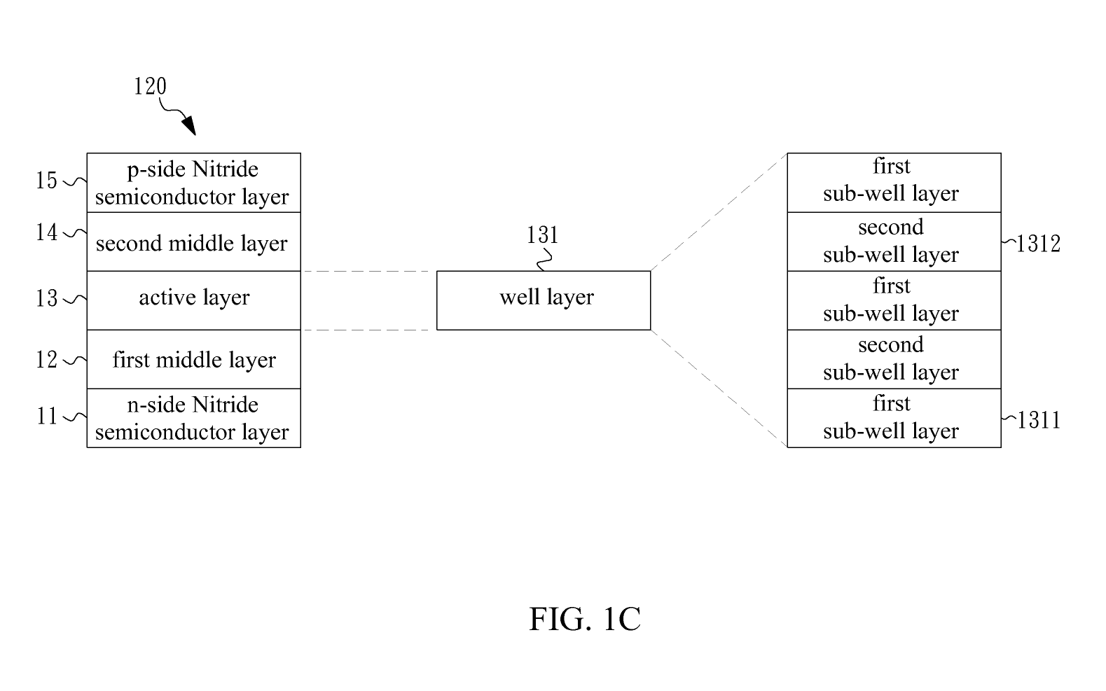

FIG. 1A shows a cross section of an embodiment of light-emitting diode (LED) device 100. For better appreciating the embodiment, drawings show layers that are most pertinent to the embodiment. LED device 100 includes at least one LED unit 10, and each LED unit 10 includes at least one LED that is a group III-nitride LED. As shown in FIG. 1A, LED unit 10 includes n-side nitride semiconductor layer 11, p-side nitride semiconductor layer 15, and active layer 13 situated between the n-side nitride semiconductor layer 11 and the p-side nitride semiconductor layer 15. N-side nitride semiconductor layer 11 may include n-type gallium nitride (GaN), and p-side nitride semiconductor layer 15 may include p-type gallium nitride. In certain embodiments, active layer 13 includes one or more well layers 131, at least one of well layers 131 may have a multilayered structure.

In some embodiments, active layer 13 is made of at least one well layer 131 and at least one barrier layer 132, which are stacked alternately. The multilayered structure of active layer 13 may be a superlattice structure. The superlattice structure may include at least one first sub-well layer 1311 and at least one second sub-well layer 1312. First sub-well layer 1311 and second sub-well layer 1312 may be stacked alternately to result in the multilayered structure. In some embodiments, first sub-well layer 1311 includes indium gallium nitride (InₓGa₁₋ₓN), and second sub-well layer 1312 includes indium gallium nitride (In_{y}Ga_{1-y}N), where the indium concentration x is different from the indium concentration y. It is noted that the indium gallium nitride with greater concentration x has a smaller energy gap than the indium gallium nitride with lesser concentration y, and barrier layer 132 (e.g., gallium nitride) has an energy gap greater than the indium gallium nitride. In some embodiments, well layer 132 includes a quaternary III-nitride such as aluminum indium gallium nitride (Al_{0.1}In_{0.2}Ga_{0.7}N) to result in a polarization-matched structure.

In some embodiments, the LED device further comprises a substrate, wherein the LED unit is disposed on the substrate. The substrate includes sapphire, germanium (Ge), silicon carbide (SiC), gallium arsenide (GaAs), zinc oxide (ZnO), or lithium aluminum oxide (—LiAlO2). In some embodiments, substrate is polar substrate, semi-polar substrate, or non-polar substrate.

In some embodiments, the substrate is a polar substrate, at least one of the first sub-well layers and at least one of the second sub-well layers each has a thickness less than or equal to 2 nanometer (nm). In some embodiments, the substrate is a semi-polar substrate or non-polar substrate, at least one of the first sub-well layers and at least one of the second sub-well layers each has a thickness less than or equal to 10 nanometer (nm). Taking polar substrate for example, as shown in FIG. 1A, well layer 131 includes at least three sub-well layers, which are approximately the same in thickness and each of which is less than or equal to 2 nanometer (nm) in thickness. Referring to FIG. 1A, well layer 131 may include at least five sub-well layers, which are approximately the same in thickness and each of which is less than or equal to 2 nanometer (nm) in thickness.

In certain embodiments, as shown in FIG. 1A, LED unit 10 may include first middle layer 12 placed between n-side nitride semiconductor layer 11 and active layer 13. First middle layer 12 may or may not contact n-side nitride semiconductor layer 11 and/or active layer 13. The LED unit may include second middle layer 14 between active layer 13 and p-side nitride semiconductor layer 15. Second middle layer 14 may or may not contact active layer 13 and/or p-side nitride semiconductor layer 15. In some embodiments, first middle layer 12 and second middle layer 14 have different constituents to result in an asymmetric structure. As shown in FIG. 1A, first middle layer 12 may include aluminum gallium nitride (AlGaN) sub-layer 121 and indium gallium nitride (InGaN) sub-layer 122. Indium gallium nitride sub-layer 122 may contact active layer 13. Second middle layer 14 may include gallium nitride (GaN) sub-layer 141 and indium gallium nitride (InGaN) sub-layer 142. Gallium nitride sub-layer 141 may contact active layer 13.

FIG. 1B and FIG. 1C show cross sections of embodiments of LED devices each having a single quantum well structure. FIG. 1B shows a cross section of conventional LED device 110. LED device 110 includes active layer 13 with single well layer 131 (with a total thickness of 5 nm). Single well layer 131 has its constituents (e.g., including In_{0.162}Ga_{0.838}N) evenly distributed. FIG. 1C shows a cross section of an embodiment of LED device 120. LED device 120 includes active layer 13 with single well layer 131 (with a total thickness of 5 nm). Single well layer 131 is a multilayered structure made of different constituents of at least one first sub-well layer 1311 (each having a thickness of 1 nm) and at least one second sub-well layer 1312 (each having a thickness of 1 nm). First sub-well layer 1311 and second sub-well layer 1312 are stacked alternately to result in the multilayered structure.

In some embodiments, first sub-well layer 1311 includes indium gallium nitride (InₓGa₁₋ₓN) and second sub-well layer 1312 includes indium gallium nitride (In_{y}Ga_{1-y}N), where the indium concentration x is different from (e.g., less than) the indium concentration y. For example, the concentration x may be equal to 0.14 and the concentration y may be equal to 0.18. It is noted that the indium gallium nitride with greater concentration x has a smaller energy gap than the indium gallium nitride with lesser concentration y.

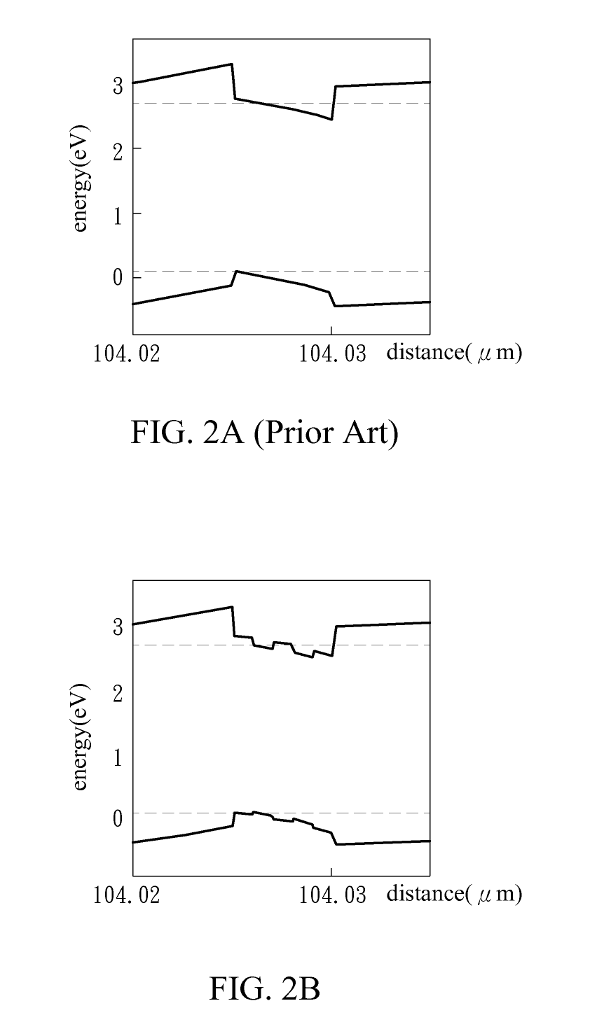

FIG. 2A shows an exemplary energy band diagram of conventional LED device 110 having a single quantum well as shown in FIG. 1B. FIG. 2B shows an exemplary energy band diagram of LED device 120 having a multilayered single quantum well as shown in FIG. 1C. According to the energy band diagram of FIG. 2B, it is observed that there are five energy gaps corresponding to the five sub-well layers 1311/1312 of the single quantum well 131.

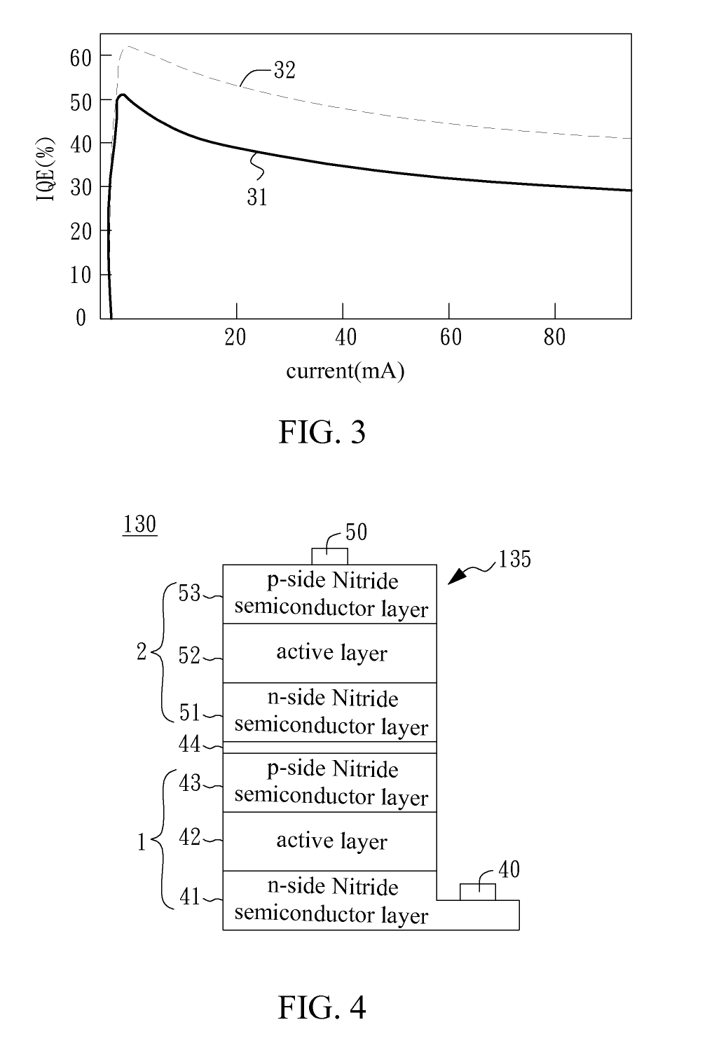

The single quantum well of LED 120 device shown in FIG. 1C may include a superlattice structure (by respectively adjusting the energy gaps of the sub-well layers). The superlattice structure may substantially increase overlapping between an electron wave function and a hole wave function, effectively shorten a photoluminescence (PL) lifetime and a carrier overflow, and effectively enhance a radioactive recombination rate and an optical gain, thereby greatly increasing luminescence efficiency. FIG. 3 shows an exemplary internal quantum efficiency (IQE) comparison between LED device 110 of FIG. 1B and LED device 120 of FIG. 1C. Curve 31 represents conventional LED device 110 having a single quantum well and curve 32 represents LED device 120 having a multilayered single quantum well. According to FIG. 3, the LED device associated with the curve 32 has a larger efficiency than the LED device associated with the curve 31.

Although a single LED is exemplified in the aforementioned embodiments, it is appreciated that the LED unit described herein may include a plurality of LEDs that are stacked. FIG. 4 shows a cross section of an embodiment of LED device 130. LED device 130 includes at least one LED unit 135, and each LED unit includes stacked LEDs. In certain embodiments, LED unit 135 includes first LED 1 and second LED 2, which are stacked via tunnel junction 44. First LED 1 may include n-side nitride semiconductor layer 41, active layer 42, p-side nitride semiconductor layer 43, and first electrode 40. In certain embodiments, active layer 42 is situated between the n-side nitride semiconductor layer 41 and p-side nitride semiconductor layer 43. First electrode 40 may be electrically connected with n-side nitride semiconductor layer 41. For example, n-side nitride semiconductor layer 41 includes n-type gallium nitride (GaN), active layer 42 includes indium gallium nitride (InGaN), and p-side nitride semiconductor layer 43 includes p-type gallium nitride. Similarly, second LED 2 may include n-side nitride semiconductor layer 51, active layer 52, p-side nitride semiconductor layer 53n and second electrode 50. In certain embodiments, active layer 52 is situated between n-side nitride semiconductor layer 51 and p-side nitride semiconductor layer 53. Second electrode 50 is electrically connected with the p-side nitride semiconductor layer 53. For example, n-side nitride semiconductor layer 51 includes n-type gallium nitride (GaN), active layer 52 includes indium gallium nitride (InGaN), and p-side nitride semiconductor layer 53 includes p-type gallium nitride. In some embodiments, active layer 42 of first LED 1 and active layer 52 of second LED 2 include the same constituent material, thereby emitting lights of the same wavelength. In other embodiments, active layer 42 of first LED 1 and active layer 52 of second LED 2 include different constituent materials, thereby emitting lights of distinct wavelengths. Relevant details may be referred, for example, to U.S. Pat. No. 6,822,991 to Collins et al., entitled “Light emitting devices including tunnel junctions,” disclosure of which is incorporated by reference as if fully set forth herein.

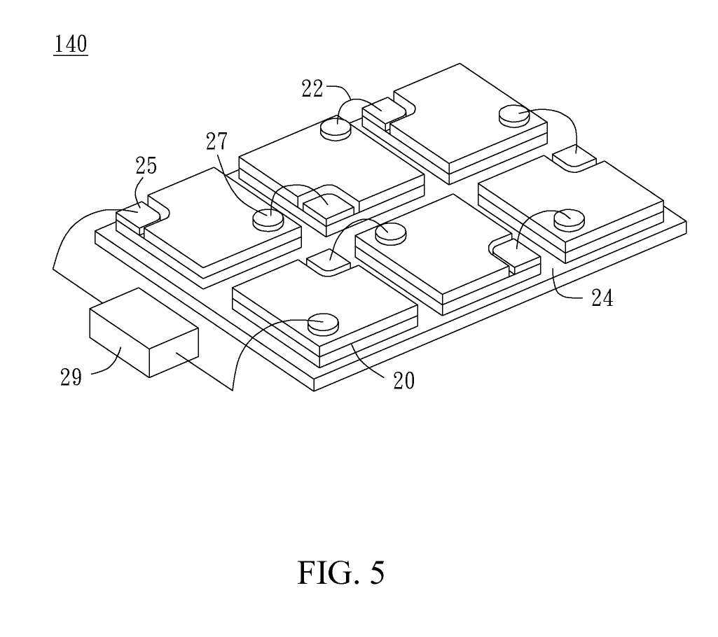

FIG. 5 shows a perspective diagram illustrating an embodiment of LED device 140. LED device 140 includes a plurality of LED units 20 that are arranged on substrate 24 in an array form. LED device 140, as shown in FIG. 5, may therefore be called an LED array. First electrode 25 of one LED unit 20 and second electrode 27 of a neighboring LED unit 20 may be electrically connected via solder wire 22 or an interconnect line. Thus, the LED units may be connected in series or parallel sequences. Taking the series connected sequence as an example, first electrode 25 of the most front LED unit 20 and second electrode 27 of the most rear LED unit 20 in the sequence are respectively connected to two ends of power supply 29. LED unit 20, as shown in FIG. 5, may be the single LED of FIG. 1A or the vertically stacked LEDs of FIG. 4.

It is to be understood the invention is not limited to particular systems described which may, of course, vary. It is also to be understood that the terminology used herein is for the purpose of describing particular embodiments only, and is not intended to be limiting. As used in this specification, the singular forms “a”, “an” and “the” include plural referents unless the content clearly indicates otherwise. Thus, for example, reference to “a device” includes a combination of two or more devices and reference to “a material” includes mixtures of materials.

Further modifications and alternative embodiments of various aspects of the invention will be apparent to those skilled in the art in view of this description. Accordingly, this description is to be construed as illustrative only and is for the purpose of teaching those skilled in the art the general manner of carrying out the invention. It is to be understood that the forms of the invention shown and described herein are to be taken as the presently preferred embodiments. Elements and materials may be substituted for those illustrated and described herein, parts and processes may be reversed, and certain features of the invention may be utilized independently, all as would be apparent to one skilled in the art after having the benefit of this description of the invention. Changes may be made in the elements described herein without departing from the spirit and scope of the invention as described in the following claims.

What is claimed is:

1. A light-emitting diode (LED) device including at least one LED unit, wherein each LED unit comprises at least one LED, each LED comprising:
an n-side nitride semiconductor layer;
a p-side nitride semiconductor layer; and
an active layer located between the n-side nitride semiconductor layer and the p-side nitride semiconductor layer;
wherein the active layer comprises one or more well layers, and wherein at least one of the well layers has a multilayered structure.

2. The LED device of claim 1, wherein the multilayered structure comprises one or more first sub-well layers and one or more second sub-well layers stacked alternately.

3. The LED device of claim 2, wherein the multilayered structure comprises a superlattice structure.

4. The LED device of claim 2, wherein the n-side nitride semiconductor layer comprises n-type gallium nitride (GaN), the p-side nitride semiconductor layer comprises p-type gallium nitride, and the first sub-well layers and the second sub-well layers comprise indium gallium nitride (InGaN).

5. The LED device of claim 4, wherein at least one of the first sub-well layers has an indium concentration different from an indium concentration of at least one of the second sub-well layers.

6. The LED device of claim 2, wherein at least one of the first sub-well layers has an energy gap different from an energy gap of at least one of the second sub-well layers.

7. The LED device of claim 2, wherein at least one of the first sub-well layers and at least one of the second sub-well layers have approximately the same thickness.

8. The LED device of claim 2, further comprising a substrate, wherein the LED unit is disposed on the substrate.

9. The LED device of claim 8, wherein the substrate is a polar substrate, at least one of the first sub-well layers and at least one of the second sub-well layers each has a thickness less than or equal to 2 nanometer (nm).

10. The LED device of claim 8, wherein the substrate is a semi-polar substrate or non-polar substrate, at least one of the first sub-well layers and at least one of the second sub-well layers each has a thickness less than or equal to 10 nanometer (nm).

11. The LED device of claim 2, further comprising:
a first middle layer located between the n-side nitride semiconductor layer and the active layer; and
a second middle layer located between the active layer and the p-side nitride semiconductor layer.

12. The LED device of claim 11, wherein the first middle layer and the second middle layer have different constituents.

13. The LED device of claim 12, wherein the first middle layer comprises an aluminum gallium nitride (AlGaN) sub-layer and an indium gallium nitride (InGaN) sub-layer, and wherein the indium gallium nitride (InGaN) sub-layer contacts the active layer.

14. The LED device of claim 12, wherein the second middle layer comprises an indium gallium nitride (InGaN) sub-layer and a gallium nitride (GaN) sub-layer, and wherein the gallium nitride (GaN) sub-layer contacts the active layer.

15. The LED device of claim 1, wherein the active layer comprises at least one barrier layer and at least one of the well layers, which are stacked alternately, and wherein the barrier layer comprises quaternary III-nitride.

16. A light-emitting diode (LED) array including a plurality of LED units arranged in an array form, wherein each LED unit comprises at least one LED, each LED comprising:
a n-side nitride semiconductor layer;
a p-side nitride semiconductor layer; and
an active layer located between the n-side nitride semiconductor layer and the p-side nitride semiconductor layer;
wherein the active layer comprises one or more well layers, and wherein at least one of the well layers has a multilayered structure;
wherein each LED unit comprises a first electrode and a second electrode, and wherein the first electrode of one LED unit and the second electrode of a neighboring LED unit are electrically connected.

17. The LED array of claim 16, wherein the LED units are electrically connected in series.

18. The LED array of claim 16, wherein the LED units are electrically connected in parallel.

19. The LED array of claim 16, wherein the multilayered structure comprises one or more first sub-well layers and one or more second sub-well layers stacked alternately.

20. A light-emitting diode (LED) device including at least one LED unit, wherein each LED unit comprises a first LED and a second LED, each LED comprising:
an n-side nitride semiconductor layer;
a p-side nitride semiconductor layer; and
an active layer located between the n-side nitride semiconductor layer and the p-side nitride semiconductor layer;
wherein the active layer comprises one or more well layers, and wherein at least one of the well layers has a multilayered structure;
wherein the first LED and the second LED are stacked via a tunnel junction.

21. The LED device of claim 20, wherein the n-side nitride semiconductor layer of the second LED is stacked on the p-side nitride semiconductor layer of the first LED via the tunnel junction.

22. The LED device of claim 20, further comprising:
a first electrode electrically connected with n-type gallium nitride of the n-side nitride semiconductor layer of the first LED; and
a second electrode electrically connected with p-type gallium nitride of the p-side nitride semiconductor layer of the second LED.

23. The LED device of claim 22, further comprising a plurality of the LED units arranged in an array form, wherein the first electrode of one LED unit and the second electrode of a neighboring LED unit are electrically connected.
